(19) United States
(12) Patent Application Publication
(10) Pub. No.: US 2026/0178795 A1
(43) Pub. Date: Jun. 25, 2026

(54) COMPUTER-IMPLEMENTED METHOD FOR CREATING A SIMULATION, HAVING A PLURALITY OF SIMULATION COMPONENTS, OF A PHYSICAL DEVICE

(71) Applicant: dSPACE GmbH, Paderborn (DE)

(72) Inventors: Martin KRONMUELLER, Paderborn (DE); Ulrich KIFFMEIER, Paderborn (DE); Rafael GILLES, Paderborn (DE)

(73) Assignee: dSPACE GmbH, Paderborn (DE)

(21) Appl. No.: 19/424,698

(22) Filed: Dec. 18, 2025

(30) Foreign Application Priority Data
Dec. 19, 2024 (DE) 10 2024 138 819.6

(51) Int. Cl. G06F 30/20

(52) U.S. Cl. CPC G06F 30/20

(57) ABSTRACT

A computer-implemented method for creating a simulation, having a plurality of simulation components of a physical device. The simulation components each can have at least one communication interface and are executable using simulation agents. The communication interfaces of the simulation components and the simulation agent types based on the simulation inventory are determined. At least one distribution of simulation components are generated that are grouped into execution processes by a communication weighting and/or a performance and/or a resource value based on the system model and the simulation inventory. A simulation application is created in which the execution processes of the distribution are associated with the simulation agent types corresponding to the requirements for the runtime environment of the simulation components that are grouped into the execution processes based on the system model. A time-, memory-, and energy-efficient computer-implemented method for creating a simulation is thus provided.

This nonprovisional application claims priority under 35 U.S.C. § 119 (a) to German Patent Application No. 10 2024 138 819.6, which was filed in Germany on Dec. 19, 2024, and which is herein incorporated by reference.

### BACKGROUND OF THE INVENTION

### Field of the Invention

The present invention relates to a computer-implemented method for creating a simulation, having a plurality of simulation components, of a physical device, the simulation components each having at least one communication interface and being executable using simulation agents, wherein a communication with at least one further simulation component is enabled via the at least one communication interface, wherein each simulation component has requirements for a runtime environment of a simulation agent type, wherein the simulation agent type is a description of the properties of the simulation agent necessary for executing the simulation component, and the simulation agent of the simulation agent type must have the runtime environment corresponding to the requirements for the runtime environment of the simulation component to allow execution of the simulation component.

There are numerous simulation tools for creating model-in-the-loop, software-in-the-loop, hardware-in-the-loop, or connected mixed-reality simulations. These simulation tools are typically made up of an editor, a compiler, a just-in-time compiler, or an interpreter in a simulation environment. The simulation defined in the editor is executable by use of the compiler, the just-in-time compiler, or the interpreter. Each of these simulation tools is typically designed for specialized fields of application. Connected mixed-reality simulations are a mixed simulation made up of real and simulated control devices.

### Description of the Background Art

A simulation agent is a simulation tool that is provided on a processing unit. This processing unit may be either a localizable processing unit or part of a compute cluster or a cloud computing solution. A simulation component that is executed on a simulation agent may be a script, which may also be present in binary format and which is portable into the editor of a simulation tool. A simulation is characterized in that it contains multiple simulation components which may have various designs and which may require similar but different simulation agents for the execution. These simulation components must thus be appropriately combined with simulation agents which enable the execution of the simulation component.

It should be noted that some simulation components are interdependent and, for example, use results of one simulation component as an input for further simulation components. Likewise, it should be noted that the simulation components communicate with one another, and are to be allocated to simulation agents in such a way that the communication among communicating simulation components is enabled. Furthermore, the simulation components have different execution periods on different simulation agents. Moreover, not all simulation agents are always available, and the available simulation agents are possibly not the most efficient choice for executing specific simulation components. For a plurality of simulation components, inefficiently associated simulation components may result in significant losses in execution speed, memory and energy requirements, and thus as a whole, efficiency of the simulation, due to the fact that the availability of the simulation agents has not been taken into account, or the associated simulation agents do not represent the most advantageous choice for certain simulation components.

### SUMMARY OF THE INVENTION

It is therefore an object of the present invention to provide a time-, memory- and energy-efficient computer-implemented method for creating a simulation.

According to an example of the invention, a computer-implemented method for creating a simulation, having a plurality of simulation components, of a physical device is thus provided, the simulation components each having at least one communication interface and being executable using simulation agents, wherein a communication with at least one further simulation component is enabled via the at least one communication interface, wherein each simulation component has requirements for a runtime environment of a simulation agent type, wherein the simulation agent type is a description of the properties of the simulation agent necessary for executing the simulation component, and the simulation agent of the simulation agent type must have the runtime environment corresponding to the requirements for the runtime environment of the simulation component to allow execution of the simulation component, wherein the communication interfaces of the simulation components are connected to one or more communication interfaces of further simulation components for the communication so that a system model is formed, and the simulation agents in the form of the simulation agent types are described in a simulation inventory, comprising the following method steps: Determining the communication interfaces of the simulation components, the connections of the simulation components with one another, and the requirements for the runtime environment of the particular simulation component based on the system model, and determining the simulation agent types based on the simulation inventory, Generating at least one distribution of simulation components that are grouped into execution processes, wherein the simulation components are grouped into execution processes by means of a communication weighting and/or a performance and/or a resource value, based on the system model and the simulation inventory, wherein a data rate between the interconnected simulation components and mutual dependencies of the simulation components are taken into account via the communication weighting, wherein execution periods of the execution of the simulation components on the simulation agent types are taken into account via the performance, wherein available simulation agent types and resource consumption of the particular simulation agent types are taken into account via the resource value, Selecting one of the distributions based on the communication weighting and/or the performance and/or the resource value, and Creating a simulation application in which the execution processes of the distribution are associated with the simulation agent types corresponding to the requirements for the runtime environment of the simulation components that are grouped into the execution processes, based on the system model, so that the execution processes are executable using simulation agents that correspond to the simulation agent types.

A computer-implemented method for creating a simulation is provided which is significantly more time-, memory-, and energy-efficient than conventional methods. By use of the invention, the available computer hardware can be utilized much more efficiently than previously, since the grouping of the simulation components into execution processes is performed according to objective criteria of the communication weighting, the performance, and the resource value.

The smallest unit of the simulation is the individual simulation component. The simulation components within a simulation simulate properties of the physical device. Each simulation component has requirements for its runtime environment. The runtime environment encompasses the specific software and hardware configurations that are necessary for executing the simulation component on the particular simulation agent. In particular, the runtime environment describes the simulation tool on a simulation agent, the number of available CPUs and GPUs, the working memory, the operating system, as well as the available memory and the type of processor or the processor architecture of the simulation agent. A processor clock speed and a processor cache of the processor, for example, are taken into account in the processor architecture. In addition, network connections or connections for communication of the individual simulation agents with one another are taken into account, which in the ultimate simulation application must allow communication of the simulation components based on the communication interfaces. The requirements for the runtime environment involve the requirements that a simulation agent must have as properties to allow execution of the simulation component in question.

According to the invention, it is provided that each simulation component is designed with at least one communication interface that enables communication with at least one further simulation component. This allows the simulation components to interact with one another, which is necessary in order to realistically simulate complex system behavior. One advantage of this arrangement is that dependencies between simulation components may be taken into account, which increases the accuracy and consistency of the simulation.

The possible types of communication in the communication interface are independent of specific simulation agents, and may be signal-based communication in the form of Model Port connections or a bus access request in the form of an automotive bus such as Ethernet, CAN, LIN, or FlexRay. The physical bus does not necessarily have to be provided in each simulation component. Rather, the physical bus for one simulation component may be provided by some other simulation component. In the context of a software-in-the-loop simulation, a physical bus is therefore not absolutely necessary. Rather, direct communication with a further simulation component is established with a virtual bus which replaces the physical bus in the simulation. In addition, the data exchange is enabled across a global data structure that is synchronized between the simulation agents.

The simulation agent type is a description of the properties of the simulation agent that is necessary for executing the simulation component. The simulation agent of the simulation agent type must thus have the runtime environment corresponding to the requirements for the runtime environment of the simulation component to allow execution of the simulation component. In principle, it is possible to provide the simulation agent types in a number of ways. In the present case, however, it is provided that the simulation agents are described in the form of the simulation agent types in the simulation inventory. The simulation inventory describes all available simulation agent types that are present in a system. The simulation inventory may have multiple simulation agents of a simulation agent type. The simulation inventory thus contains all available simulation agent types. This simulation inventory is preferably listed in a database or a data memory which can be accessed by the computer-implemented method according to the invention.

Interconnected simulation components now form the system model. Thus, the communication interfaces of the simulation components, the requirements for the runtime environment of each simulation component, and connections of the communication interfaces of the simulation components with one or more communication interfaces of further simulation components are described in the system model. Based on the system model, it is possible to determine the interconnections of the simulation components, as a result of which dependencies and communication paths between simulation components are detected, which allows precise and efficient distribution of the components. The communication interfaces, i.e., the type of communication, and the requirements for the runtime environment of the particular simulation component are likewise determined based on the system model.

The method according to the invention further provides that at least one distribution of simulation components that are grouped into execution processes is generated, wherein the simulation components are grouped into execution processes using a communication weighting and/or a performance and/or a resource value, based on the system model. This allows flexible and efficient grouping of the simulation components in the execution processes, based on their communication requirements, their execution period, and the available resources.

A data rate between the interconnected simulation components and mutual dependencies of the simulation components can be taken into account via the communication weighting. For example, simulation components in a so-called blocking mode may be mutually dependent. In this case, certain simulation components can be executed only when other simulation components have already been previously executed. As a whole, this ensures that the communication requirements of the simulation components are optimally taken into account, which improves the communication latency and communication bandwidth within the simulation. One advantage is that the efficiency of the simulation is increased due to an improved data transfer rate and reduced communication delays, which facilitates utilization of parallelizable processes.

The method according to the invention further provides that execution periods of the execution of the simulation components on the simulation agents of the simulation agent types are taken into account via the performance, which in turn allows assessment of the execution duration of the simulation components on various simulation agent types, and corresponding improvement of the distribution. This reduces the overall execution time of the simulation and improves capacity utilization of the simulation agents.

It is further provided that availability of the simulation agent types and resource consumption of the particular simulation agent types can be taken into account via the resource value. Optimal use is thus made of the available resources, and the resource consumption is reduced. The resource value may be such that a high resource value is associated with high costs, and a corresponding low resource value is associated with low costs. Thus, one advantage is that the costs for carrying out the simulation are lowered and the resources are utilized more efficiently. The available simulation agent types are those simulation agent types that are not involved in other simulation applications or possibly disconnected at the time of the simulation. In particular, the available simulation agent types are available for the simulation application.

Moreover, one of the generated distributions can be selected based on the communication weighting and/or the performance and/or the resource value, and a simulation application is created in which the execution processes of the distribution are associated with the simulation agent types corresponding to the requirements for the runtime environment of the simulation components that are grouped into the execution processes, based on the system model, so that the execution processes are executable using simulation agents corresponding to the simulation agent types. This ensures that the simulation components grouped into execution processes are executed on the available simulation agents according to the most efficient distribution possible. One advantage of this arrangement is that the simulation can be carried out more quickly and with greater conservation of resources, which improves the overall efficiency and cost-effectiveness of the simulation. In the present case, resources are understood to mean the simulation agents of the simulation agent types and their runtime environment. “Conservation of resources” thus may correspond to a reduction in the resource consumption of the following resources: simulation agent or simulation agent type.

The simulation agents can be configured to be able to execute hardware-in-the-loop, software-in-the-loop, model-in-the-loop, or connected mixed-reality simulations. The connected simulation components form the system model. This is independent of the subsequent execution of the simulation application and in particular of the type of simulation. Model-in-the-loop, software-in-the-loop, hardware-in-the-loop, or connected mixed-reality simulations may thus be executed using the same, unchanged system model.

In principle, the simulation components may be grouped into the execution processes in various ways. According to an example, it is provided that selected simulation components may be inserted into individual execution processes or grouped into separate execution processes by an end user. An advantage of this arrangement is that the end user obtains more control and flexibility in configuring the simulation, resulting in improved adaptation of the simulation to specific requirements.

The simulation agents can have simulation agent interfaces, wherein the simulation agent interfaces may be connected for communication with one or more simulation agent interfaces, and the computer-implemented method comprises the following further steps: Selecting the simulation agent types required for an execution of the execution processes, and Forming a simulation agent type network based on the required simulation agent types and based on the connections, necessary for the communication, between the simulation agents of the required simulation agent types.

Communication between the simulation components on different simulation agents may be enabled, taking into account the particular simulation agent interfaces. For example, the exchange of data across a global data structure that is synchronizable between the simulation agents is made possible. The required simulation agent types are those simulation agent types that are needed for the execution of the simulation application, i.e., the execution processes, taking into account the selected distribution. Communication between the simulation agents may be necessary for executing the execution processes, depending on the requirements of the simulation components. The communication is specified by the execution processes. The simulation agent type network is therefore formed in such a way that the simulation agent types of simulation agents that must communicate with one another via the simulation agent interfaces for execution of the simulation application are contained in the simulation agent type network.

The connections between the simulation agents, necessary for communication, accordingly enable the communication between the simulation agents that is necessary for executing the execution processes. The simulation agent type network is thus formed based only on the requirements given by the execution units. This advantageously results in freedom in combining the simulation agent types, wherein forming the simulation agent type network ensures that the connections for communication of the simulation agents corresponds to the connections required for executing the simulation application. For the specific execution of the simulation application, a simulation agent network of simulation agents that are interconnected for the communication, corresponding to the simulation agent type network, may then be formed.

The method additionally can comprise a simulation agent type network, wherein the simulation agents have simulation agent interfaces, wherein the simulation agent interfaces are connected for communication with one or more simulation agent interfaces of further simulation agents, and the simulation agent type network has simulation agent types of simulation agents that are interconnected for the communication, comprising the following further step: Selecting the simulation agent types of the simulation agent type network that are necessary for executing the execution processes. Unlike the situation in the previous embodiment, here the simulation agent type network already includes the simulation agent types necessary for the execution, and does not have to first be formed. The selection corresponds to an association. A simulation agent type is selected for or associated with each execution process.

In this context, the method can include a plurality of simulation agent type networks, comprising the following steps: Determining simulation agent type networks from the plurality of simulation agent type networks contained by the simulation agent types that are necessary for executing the execution processes, and Selecting a simulation agent type network from the determined simulation agent type networks, taking into account the communication weighting and/or the performance and/or the resource value. It should be noted that for each simulation agent type network, a plurality of identical simulation agent networks may be present which may possibly not be available, based on their particular capacity utilization and taking into account the resource value. Correspondingly, the other simulation agent networks would then be available, for example, so that the simulation application would then run on one of these alternatives. One advantage of this arrangement is thus that multiple options for the resource distribution may be checked, and the distribution that is particularly advantageous according to the communication weighting and/or the performance and/or the resource value may be selected, which further improves the flexibility and efficiency of the simulation.

A further embodiment of the invention provides that the computer-implemented method comprises the following further steps: Providing a simulation agent inventory that contains the simulation agents corresponding to the simulation agent types of the simulation agent type network, and Executing the simulation application, using the simulation agents of the simulation agent inventory.

The simulation components may correspondingly be executed directly with the simulation agents, based on the simulation inventory. Providing a simulation agent inventory allows quicker retrievability of the available simulation agents. A simulation agent inventory may be understood as a list, on a database or a data memory, which contains all simulation agents that are necessary for executing the individual simulation components. One advantage of this arrangement is that the association of the simulation components with the simulation agents is clearly defined and traceable, which facilitates management and optimization of the simulation.

In principle, it is possible to group the simulation components in execution processes in various ways. The method can comprise the following further steps: Identifying compatible simulation components for each simulation agent type, wherein the particular compatible simulation component has requirements for the runtime environment that correspond to the particular simulation agent type, wherein during generation of the distribution, simulation components having incompatible requirements for the runtime environment of a simulation agent type are grouped into different execution processes, Classifying the execution processes of the distribution for identical simulation agent types into execution units, and During the creation of the simulation application, instead associating the execution units with the simulation agent types.

Simulation components having compatible requirements for the runtime environment are executable together with a simulation agent type having the corresponding description of the properties. It is not necessary for the requirements for the runtime environment of the simulation components to be identical. Instead, it is sufficient if the requirements for the runtime environment of the various simulation components do not collide with one another with regard to the particular simulation agent type. Therefore, two simulation components, which for example require different simulation tools for the execution, cannot both be classified into an execution process when a simulation agent type having only one of the necessary simulation tools is associated with the execution process. It is possible to execute mutually incompatible simulation components on different simulation agents, so that the simulation agents are not held back due to incompatible simulation components, which then would require a redistribution. Classifying the execution processes of the distribution into execution units for identical simulation agent types reduces the complexity of the selected distribution, so that the simulation agents can access the simulation components more quickly.

In principle, the communication weighting may be formed in various ways. The communication weighting can be determined based on the connections between the simulation components, wherein each connection between the simulation components is provided with a distance weighting, the distance weighting is given by the data rate between the simulation components and the dependencies of mutually dependent simulation components, the simulation components are grouped into joint execution processes of the particular distribution, based on the distance weightings of the connections, and the communication weighting is a sum of all distance weightings of the connections between simulation components in various execution processes of the particular distribution. Accordingly, the lower the communication weighting, the better the performance of the distribution of the simulation components in the various execution processes. In the present case, “data rate” is understood to mean a volume of data that must be transferred per unit time between the simulation components. Simulation components having a high data rate or a large data volume to be transferred are therefore preferably combined in one execution process, since the data rate or transfer rate is generally slower over different execution processes or between simulation agents of different simulation agent types. The distance weighting is thus given by the data rate and the dependencies of the simulation components. The higher the data rate, the greater the corresponding distance weighting. Dependencies between the simulation components, which suggest a joint execution on a simulation agent, may accordingly imply the highest distance weighting. One advantage is that optimal use is made of the connections between the simulation components, and the communication latencies are reduced, which improves the efficiency of the simulation.

A further embodiment of the invention provides that the simulation components are grouped into the execution processes based on the distance weightings, using partitioned clustering and/or density-based clustering and/or spectral clustering.

In partitioned clustering, the simulation components are subdivided into a predefined number of clusters or execution processes. The fixed number of execution processes is correspondingly determined via the specific available simulation agent types. This includes the K-means method, which efficiently operates by specifying cluster centers and grouping the simulation components based on a minimum distance from these cluster centers. One advantage of this method is its computing power efficiency for large data sets, in particular when repetition of calculations over multiple iterations is involved.

Density-based clustering, such as DBSCAN, is based on a density of data points or simulation components in a space. Areas with a high point density are grouped into the execution processes. This method is particularly effective for processing data having complex structures, and can recognize any form of cluster without specifying an explicit number. In addition, the method is robust with respect to outliers, which offers a technical advantage when handling data volumes that contain extreme deviations or noise.

In spectral clustering, a similarity matrix of the data points or simulation components is first analyzed, and is projected into a low-dimensional space by eigendecomposition before it is further grouped into execution processes, using a clustering method such as K-means. This method is efficient in identifying nonlinear structures.

The simulation components can be grouped into the execution processes in such a way that the communication weight is minimal, and the dependencies of mutually dependent components minimally block the execution of the simulation. One advantage is that optimal use of made of the connections between the simulation components, and the communication latencies are reduced, which improves the efficiency of the simulation.

It is possible to depict the performance in various ways. The performance Pᵥ of the particular distribution v for all execution processes g=1, 2, . . . , N_{g} can be determined using the following formula:

$$where$$

$${P}_{v} = max ( {P}_{v , 1} , {P}_{v , 2} , … , {P}_{v , {N}_{ℊ}} ) , mit {P}_{v , ℊ} = \frac{{T}_{{S}_{v , ℊ}}}{{T}_{{V}_{v , ℊ}}} ,$$

where P_{v,g} is the performance of an execution process, T_{S}_{_{v,g}} is an execution period of the particular execution process on the simulation agent, and Typo is a virtual time period of the execution in the particular execution process. Thus, the virtual time period corresponds to the time that elapses during the execution process, i.e., of a simulated environment during the execution thereof. The virtual time period is the time used by the execution process for its own calculation. This correspondingly also extends to the simulation components in the particular execution process. Since the simulation application generally runs synchronously, the performance of the distribution results from the poorest, i.e., the highest, performance value of all execution processes of the distribution. One advantage is that precise synchronization and assessment of the simulation components are enabled, thus improving the efficiency of the simulation. Taking into account the virtual time period allows precise coordination of the execution processes, which results in better utilization of the computing power. Due to the clear separation between virtual time and real time in the form of the execution period, the simulation can be carried out realistically and efficiently. For real-time applications the execution period must be shorter than the virtual period, wherein for real-time applications the virtual time period corresponds to the real time period. An advantageous ratio for real-time applications would therefore be P_{v,g}<1, in particular P_{v,g}<0.7. A further advantage is that the performance of the execution processes can be precisely assessed and improved, for example by selecting simulation agent types that allow a shorter execution period, which improves the efficiency and the execution time of the overall simulation.

The simulation components can be grouped into the execution processes in such a way that the performances of the execution processes are homogeneously distributed. In the present case, “homogeneously distributed” means that all performances are identical or lie within predetermined limits. One advantage is that the processing load is uniformly distributed over the available resources, which increases the efficiency and stability of the simulation.

The performance Pᵥ of the particular distribution v for all execution processes g=1, 2, . . . , N_{g} can be determined using the following formula:

$$where$$

$${P}_{v} = max ( {P}_{v , 1} , {P}_{v , 2} , … , {P}_{v , {N}_{g}} ) , mit {P}_{v , g} = {\sum }_{c = 1}^{{N}_{c}} {U}_{g , c} ,$$

where P_{v,g} is the performance of an execution process, Nc is the number of simulation components in an execution process, and U_{g,c} is a processor utilization achieved with a simulation component. The processor utilization U_{g,c} is the proportion of the processor time that is necessary for executing a certain simulation component, relative to the total available processor time. The simulation is calculated in clocked simulation steps that are organized via tasks. The simulation steps are executed in tasks having a matching sample time. For each task a period duration is specified, within which the task with its execution period is calculated. As a result, the execution period must be shorter than the period. In the case of a software-in-the-loop simulation, the tasks are triggered as soon as the calculation of a preceding task is completed. The efficiency of the simulation may be maximized by taking into account the processor utilization, since overloads are avoided and an improved distribution of the resources may be made. This results in improved utilization of the simulation agents, since the simulation components are distributed in such a way that the processor time is evenly utilized. The overall execution time of the simulation is thereby shortened. This arrangement also allows more precise planning and scaling of the resources.

The execution processes can be distributed dynamically over the available processor cores, so that the performance is determined using the following formula:

$${P}_{v} = {\sum }_{g = 1}^{{N}_{g}} \frac{{P}_{ℊ}}{{N}_{K}} ,$$

where N_{K} is the number of available processor cores, P_{g} is the performance of an execution process, and N_{g} is the number of execution processes.

In principle, the execution period of the simulation components may be determined in various ways. The execution period of each simulation component can be determined in a preceding reference phase on a simulation agent of each of the simulation agent types, so that the execution period for each simulation component on each simulation agent is known. Thus, for each simulation component the execution period of each task is determined for each simulation agent type on which the simulation component is executable. One advantage of this arrangement is that the performance of the simulation can be assessed and improved in advance, which increases the accuracy of the prediction of the execution period of the simulation. Similarly, the method according to the invention is thus carried out much more quickly.

The execution period of each simulation component on a simulation agent of each simulation agent type can be extrapolated to the particular simulation agent, based on an execution period that is required for executing a reference component. For this purpose, performance factors of the individual simulation agent types are determined based on a reference component. A measurement of the execution period of the reference component is performed using a reference simulation agent type as well as measurements of the execution period of the reference component on the particular simulation agent type. The performance factor is formed by a ratio of these two execution periods. The execution periods of the simulation component on the simulation agent of the simulation agent type correspondingly result, based on the linear relationship that is formed via the performance factor, and may be extrapolated. One advantage of this arrangement is that performances of the individual distributions can be determined more quickly.

In principle, it is possible to determine the execution periods during the creation of each simulation application. The execution period of each simulation component can be described in the system model.

The execution periods of the simulation component on the particular simulation agent type can be successively stored in the system model upon each creation of a simulation application with the particular simulation component. Precise execution periods for the particular simulation components are collected in conjunction with the simulation agent types on which the simulation components are executed, so that the execution periods and thus the performance with an increasing number of simulation applications are determined with continuously better accuracy and greater speed.

In principle, the resource value may be formed in various ways. The resource value can take into account the resource consumption of the simulation agent types by decreasing the resource value for a simulation agent type having a runtime environment that corresponds to the minimum requirements of the simulation component for the runtime environment, and by increasing the resource value for a simulation agent type having a runtime environment that exceeds the minimum requirements of the simulation component for the runtime environment. A low resource value thus corresponds to reduced resource consumption with simulation agent types that correspond to the low resource consumption, and a high resource value corresponds to an increased resource consumption with simulation agent types that correspond to the increased resource consumption. Thus, in the present case, requirements for the runtime environment which exceed the minimum requirements for the runtime environment are, for example, those simulation agent types having a processor with more cores or a larger working memory or a faster processor clock speed or a better graphics card than at least that needed for executing the simulation component. One advantage is that the resource utilization is improved and unnecessary resource consumption is avoided, which increases the efficiency of the simulation.

It is possible to select the distribution based on various criteria. The method can comprises the following further steps: determining a performance indicator for each distribution, based on the communication weighting and/or the performance and/or the resource value, and Selecting a distribution based on the performance indicator. In this way the most advantageous distribution of the simulation components is selected based on multiple criteria, which improves the efficiency and performance of the simulation.

The performance indicators can be determined during a preceding reference phase and described in the system model. This greatly reduces calculation times for the performance indicator during creation of the simulation.

The distribution with the lowest performance indicator can be selected, wherein the performance indicator for each distribution corresponds to the sum of the communication weighting and/or the performance and/or the resource value of the particular distribution. The most efficient and resource-conserving distribution of the simulation components is selected in this way.

The performance indicator as well as the communication weighting and/or the performance and/or the resource value can be output so that an end user can select the distribution. This increases the flexibility in the design of the simulation.

The invention further relates to a nonvolatile, computer-readable memory medium with commands stored thereon, which when executed on a processor implement the computer-implemented method described above.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a flow chart for a method according to an example of the invention,

FIG. 2 schematically shows creation of a distribution of simulation components, grouped into execution processes, according to an example, and

FIG. 3 schematically shows a simulation application according to an example of the invention.

### DETAILED DESCRIPTION

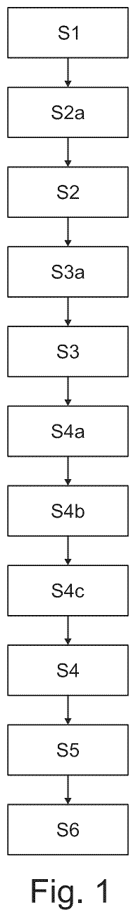

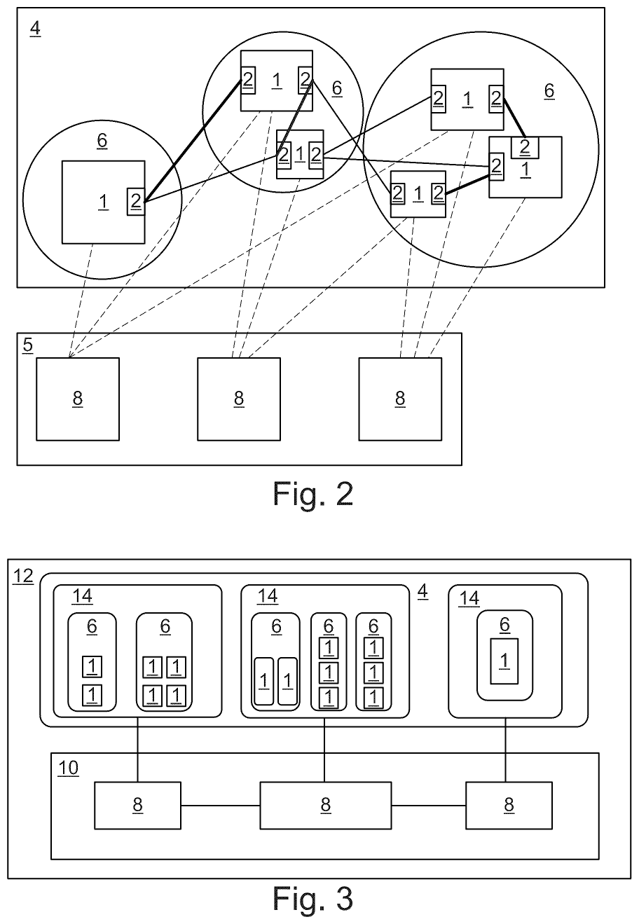

FIG. 1 shows a flow chart for a method according to one preferred exemplary embodiment of the invention. A simulation of a physical device is created using this computer-implemented method. The simulation has a plurality of simulation components 1, which are apparent in FIGS. 2 and 3. Each of these simulation components 1 has at least one communication interface 2 that enables communication with at least one further simulation component 1. The simulation components 1 are executable using simulation agents, not shown here. The simulation agents, in the form of simulation agent types 8, are described in a simulation inventory 5 that is provided on a data memory. There are multiple simulation agents of a simulation agent type 8 in the simulation inventory 5. The simulation inventory 5 includes all available simulation agent types 8. Each simulation component 1 has requirements for a runtime environment. The simulation agent of the simulation agent type 8 must have the runtime environment corresponding to the requirements for the runtime environment of the simulation component 1 to allow execution of the simulation component.

The simulation components 1, which are interconnected corresponding to their communication interfaces 2, form a system model 4. Based on the system model 4 and the simulation agent types 8 described in the simulation inventory 5, communication interfaces 2 of the simulation components 1, the connections of the simulation components to one another, and the requirements for the runtime environment of the particular simulation component 1 as well as the available simulation agent types 8 are determined in a first step S1. Compatible simulation agent types 8 for each simulation component 1 are identified in a further step S2a. The simulation components 1 are compatible when they have the requirements for the runtime environment that correspond to the simulation agent type. Distributions of simulation components 1 that are grouped into execution processes 6 are generated in step S2. Simulation components 1 with incompatible requirements for the runtime environment of a simulation agent type 8 are always grouped into different execution processes 6.

FIG. 2 shows the generation of a distribution based on a communication weighting. First, the simulation components 1 are grouped based on their compatibility. The compatibilities of the simulation components 1 with the simulation agent types 8 in the simulation inventory 5 are traceable via the dashed lines. A data rate between the interconnected simulation components 1 and mutual dependencies of the simulation components 1 are taken into account via the communication weighting. In FIG. 2, higher data rates are provided with a more distinctly emphasized communication connection than lower data rates. Each of these connections is provided with a distance weighting. Connections between two mutually dependent simulation components 1 in the blocking mode are provided with the highest distance weighting G_{K}_{_{SB}}, so that these simulation components 1 are preferably executed on a simulation agent type 8 or grouped into an execution process 6.

Connections or communication without a blocking dependency are provided with the distance weighting Gx, via the data rate, a data volume that is transferred in a fixed unit of time. The following expression applies:

$${G}_{{K}_{S}} = \frac{DR}{{DR}_{N}} ,$$

where DR is the data rate and DR_{N} is a freely selectable normed data rate. For example, a maximum data rate of

$${DR}_{N} = 1 \frac{Gbit}{S} ,$$

for example, may be used for this purpose. This maximum data rate would then be the maximum data rate that can be achieved between simulation agent types of the simulation agent type network.

Simulation components 1 having a low data rate are particularly suited for being grouped into various execution processes 6. In reality, simulation components 1 that are interconnected via virtual buses would likewise be connected via buses, and therefore are particularly suited for being grouped into various execution processes 6. Such connections are provided with the distance weighting G_{K}_{_{VB}}.

Accordingly, the individual distance weightings preferably meet the following condition:

$${G}_{{K}_{SB}} \geq {G}_{{K}_{S}} > {G}_{{K}_{VB}} .$$

Simulation components 1 with connections having distance weightings G_{K}_{_{SB}} are preferably grouped into the same execution process 6. Simulation components 1 having a distance weighting Gs are grouped into the same execution processes 6 when they have a high data rate. Simulation components 1 having a distance weighting G_{K}_{_{VB}} are preferably grouped into different execution processes 6, since a distribution over different processing units is provided for them for the actual implementation, and for optimizing the simulation the option it is thus provided to place other simulation components 1, which have an increased need to be simulated close together, in a joint execution process 6. Density-based clustering is used for the grouping based on the distance weighting. In the distributions, clustering parameters are varied in particular to differently into the group the simulation components 1, having distance weightings G_{K}_{_{SB′}} different distributions.

Lastly, the communication weighting G_{K} is formed by the sum of all distance weightings in the particular distribution. The distribution with the lowest communication weighting is the most advantageous.

For the distributions thus obtained, performances Pᵥ of the particular distribution v are subsequently determined for all execution processes g=1, 2, . . . , N_{g} as follows:

$$where$$

$${P}_{v} = max ( {P}_{v , 1} , {P}_{v , 2} , … , {P}_{v , {N}_{g}} ) , mit {P}_{v , g} = {\sum }_{c = 1}^{{N}_{c}} {U}_{g , c} .$$

where P_{v,g} is the performance of an execution process, Nc is the number of simulation components in an execution process, and U_{g,c} is a processor utilization achieved with a simulation component. The processor utilization U_{g,c} is the proportion of the processor time that is necessary for executing a certain simulation component, relative to the total available processor time. The simulation is calculated in clocked simulation steps that are organized via tasks i. The simulation steps are executed in tasks i having a matching sample time. An important property is the execution period C_{i,c} of a simulation component c within a task i that is calculated with a period Tᵢ. In the case of a real-time application, in which the tasks i with the real time are triggered, the calculation of the simulation component c requires the processor utilization

$${U}_{c} = {\sum }_{i = 1}^{{N}_{t}} \frac{{C}_{i , c}}{{T}_{i}} ,$$

where Nₜ corresponds to the number of tasks i for which the simulation component provides calculation steps. The execution periods of the simulation components 1 on the simulation agent types 8 are determined using performance factors F of the individual simulation agent types s, based on a reference component c. The performance factor Fₛ for a simulation agent type s results from

$${F}_{S} = \frac{{C}_{i , s , {c}_{r}}}{{C}_{i , {s}_{r} , {c}_{r}}} ,$$

where C_{i,s,c}_{ᵣ} is the measured execution period of the reference component cᵣ on the simulation agent type s, and C_{i,s}_{ᵣ}_{,c}_{ᵣ} is the measured execution period of the reference component cᵣ on a reference simulation agent type sᵣ. If it is assumed that the difference in performance between the simulation agent types is not a function of the task i, it is not necessary to individually determine the performance factor F for each task i. Therefore, for determining the execution period of the simulation component c for all simulation agent types s, it is necessary only to perform a measurement of the execution period C_{i,s}_{ᵣ}_{,c} with the reference simulation agent type sᵣ. The execution periods for the further simulation agent types result as follows:

$${C}_{i , s , c} = {F}_{S} \times {C}_{i , {s}_{r} , c} .$$

Similarly, for the given distributions, resource values are determined which take into account on the one hand the available simulation agent types 8 in the simulation agent type network, and on the other hand the resource consumption of the particular simulation agent types 8. The resource value is correspondingly decreased when the specific simulation agent type 8 for executing the execution process 6 meets the minimum requirements of the simulation components 1 in this execution process 6. The resource value is increased when the specific simulation agent type 8 for executing the execution process 6 exceeds the minimum requirements of the simulation components 1 in this execution process 6.

A performance indicator is now determined in step S3a for each of the distributions by summation of the communication weighting and the performance and the resource value. The distribution with the lowest performance indicator is selected in step S3.

A simulation agent type network 10 has simulation agent types 8 of interconnected simulation agents. The simulation agents have simulation agent interfaces. By use of the simulation agent interface, the simulation agent may be connected for communication with one or more simulation agent interfaces of further simulation agents. Network connections of the simulation agent types 8 in the simulation agent type network 10 describe the possible connections of the simulation agents with one another, so that it may be identified which communication between the simulation components 1, on which simulation agents or with which distribution, is achievable. A plurality of simulation agent type networks 10 with corresponding simulation agent types 8 are now present.

It is therefore provided in step S4a to determine the simulation agent type networks 10, of the plurality of simulation agent type networks 10, which contain the simulation agent types 8 that are necessary for executing the execution processes 6, in order to then select, in the subsequent step S4b, a simulation agent type network 10, shown in FIG. 3, from the determined simulation agent type networks 10, taking into account the communication weighting and the performance and the resource value. The execution processes of the distribution for identical simulation agent types 8 of the simulation agent type network 10 are classified into execution units 14 in step S4c.

A simulation application 12, apparent in FIG. 3, is created in step S4. For this purpose, execution units 14 having the execution processes 6 are associated with simulation agent types 8 in the simulation agent type network 10 corresponding to the requirements for the runtime environment of the simulation components 1 that are grouped into the execution processes 6. The simulation agent types 8 are connected to one another corresponding to the simulation agent type network 10, so that even simulation components 1 in different execution units 14 can communicate with one another. In the subsequent step S5 a simulation agent inventory is provided which contains the simulation agents corresponding to the simulation agent types 8 of the simulation agent type network 10. Lastly, the simulation application 12 is executed in a final step S6, using the simulation agents.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A computer-implemented method for creating a simulation comprising at least two simulation components of a physical device, the simulation components each having at least one communication interface and are executable using simulation agents, wherein a communication with at least one further simulation component is enabled via the at least one communication interface, wherein each simulation component has requirements for a runtime environment of a simulation agent type, wherein the simulation agent type is a description of properties of the simulation agent necessary for executing the simulation component, and the simulation agent of the simulation agent type has the runtime environment corresponding to the requirements for the runtime environment of the simulation component to allow execution of the simulation component, wherein the communication interfaces of the simulation components are connected to one or more communication interfaces of further simulation components for the communication so that a system model is formed, and the simulation agents in the form of the simulation agent types are described in a simulation inventory, the method comprising:
determining the communication interfaces of the simulation components, connections of the simulation components with one another, and requirements for the runtime environment of the particular simulation component based on the system model;
determining the simulation agent types based on the simulation inventory;
generating at least one distribution of simulation components that are grouped into execution processes, the simulation components being grouped into execution processes by a communication weighting and/or a performance and/or a resource value based on the system model and the simulation inventory, wherein a data rate between the interconnected simulation components and mutual dependencies of the simulation components are taken into account via the communication weighting, wherein execution periods of the execution of the simulation components on the simulation agent types are taken into account via the performance, wherein available simulation agent types and resource consumption of the particular simulation agent types are taken into account via the resource value;
selecting one of the distributions based on the communication weighting and/or the performance and/or the resource value; and
creating a simulation application in which the execution processes of the distribution are associated with the simulation agent types corresponding to the requirements for the runtime environment of the simulation components that are grouped into the execution processes, based on the system model, so that the execution processes are executable using simulation agents that correspond to the simulation agent types.

2. The method according to claim 1, wherein the simulation agents have simulation agent interfaces, wherein the simulation agent interfaces are adapted to be connected for communication with one or more simulation agent interfaces, and wherein the method further comprises:
selecting the simulation agent types required for an execution of the execution processes; and
forming a simulation agent type network based on the required simulation agent types and based on the connections necessary for the communication between the simulation agents of the required simulation agent types.

3. The method according to claim 1, wherein, in a simulation agent type network, the simulation agents have simulation agent interfaces, wherein the simulation agent interfaces are connected for communication with one or more simulation agent interfaces of further simulation agents, and the simulation agent type network has simulation agent types of interconnected simulation agents for the communication, and wherein the method further comprises:
selecting the simulation agent types of the simulation agent type network that are necessary for an execution of the execution processes.

4. The method according to claim 1, wherein, in a plurality of simulation agent type networks, the method further comprises:
determining simulation agent type networks from the plurality of simulation agent type networks that contain the simulation agent types necessary for executing the execution processes; and
selecting a simulation agent type network from the determined simulation agent type networks taking into account the communication weighting and/or the performance and/or the resource value.

5. The method according to claim 1, further comprising:
providing a simulation agent inventory that contains the simulation agents corresponding to the simulation agent types of the simulation agent type network; and
executing the simulation application using the simulation agents of the simulation agent inventory.

6. The method according to claim 1, further comprising:
identifying compatible simulation components for each simulation agent type, wherein the particular compatible simulation component has requirements for the runtime environment that correspond to the particular simulation agent type, wherein simulation components having incompatible requirements for the runtime environment of a simulation agent type are grouped into different execution processes in the step of generating at least one distribution of simulation components;
classifying the execution processes of the distribution for identical simulation agent types into execution units; and
associating, during the creation of a simulation application, associating the execution units with the simulation agent types in the step of creating a simulation application.

7. The method according to claim 1, wherein in the step of generating at least one distribution of simulation components, the communication weighting is determined based on the connections between the simulation components, wherein each connection between the simulation components is provided with a distance weighting that is given by the data rate between the simulation components and the dependencies of mutually dependent simulation components, wherein the simulation components are grouped into joint execution processes of the particular distribution, based on the distance weightings of the connections, and wherein the communication weighting is a sum of all distance weightings of the connections between simulation components in various execution processes of the particular distribution.

8. The method according to claim 1, wherein a performance Pᵥ of the particular distribution v for all execution processes g=1, 2, . . . , N_{g} is determined in the step of generating at least one distribution of simulation components using the following formula:
$$where$$
$${P}_{v} = max ( {P}_{v , 1} , {P}_{v , 2} , … , {P}_{v , {N}_{ℊ}} ) , mit {P}_{v , ℊ} = \frac{{T}_{{S}_{v , ℊ}}}{{T}_{{V}_{v , ℊ}}} ,$$
where P_{v,g} is the performance of an execution process, T_{S}_{_{v,g}} is an execution period of the particular execution process on the simulation agent, and T_{V}_{_{v,g}} is a virtual time period of the execution in the particular execution process.

9. The method according to claim 1, wherein the simulation components are grouped into the execution processes such that the performances of the execution processes are homogeneously distributed.

10. The method according to claim 8, wherein the execution period of each simulation component has been determined in a preceding reference phase on a simulation agent of each of the simulation agent types so that the execution period for each simulation component on each simulation agent is known.

11. The method according to claim 8, wherein the execution period of each simulation component on a simulation agent of each simulation agent type is extrapolated to the particular simulation agent based on an execution period that is required for executing a reference component.

12. The method according to claim 1, wherein in the step of generating at least one distribution of simulation components, the resource value takes into account the resource consumption of the simulation agent types by decreasing the resource value for a simulation agent type having a runtime environment that corresponds to the minimum requirements of the simulation component for the runtime environment, and by increasing the resource value for a simulation agent type having a runtime environment that exceeds the minimum requirements of the simulation component for the runtime environment.

13. The method according to claim 1, further comprising:
determining a performance indicator for each distribution based on the communication weighting and/or the performance and/or the resource value; and
selecting a distribution based on the performance indicator.

14. The method according to claim 13, wherein the distribution with the lowest performance indicator is selected, wherein the performance indicator for each distribution corresponds to the sum of the communication weighting and/or the performance and/or the resource value of the particular distribution.

15. A nonvolatile, computer-readable memory medium with commands stored thereon, which when executed on a processor implement the method according to claim 1.
